(19) United States
(12) Patent Application Publication
(10) Pub. No.: US 2020/0209742 A1
(43) Pub. Date: Jul. 2, 2020

(54) METHOD OF PRODUCING MICROSTRUCTURE AND METHOD OF PRODUCING LIQUID EJECTION HEAD

(71) Applicant: CANON KABUSHIKI KAISHA, Tokyo (JP)

(72) Inventors: Satoshi Tsutsui, Yokohama-shi (JP); Kazunari Ishizuka, Suntou-gun (JP); Isamu Horiuchi, Yokohama-shi (JP); Yohei Hamade, Tokyo (JP); Miho Ishii, Kawasaki-shi (JP)

(21) Appl. No.: 16/722,825

(22) Filed: Dec. 20, 2019

(30) Foreign Application Priority Data
Dec. 27, 2018 (JP) 2018-246290

(51) Int. Cl. G03F 7/039; G03F 7/20; G03F 7/16; G03F 7/30

(52) U.S. Cl. CPC G03F 7/039; G03F 7/30; G03F 7/162; G03F 7/20

(57) ABSTRACT

Provided is a method of producing a microstructure including: forming a resin layer from a photosensitive resin composition on a substrate; exposing the resin layer to a microstructure pattern to form a cured portion as a result of the exposure and an uncured portion as a result of non-exposure; and removing the uncured portion from the substrate through development to provide a microstructure pattern having the cured portion, wherein the photosensitive resin composition to be used contains an epoxy resin, a crosslinking agent containing a polyhydric alcohol that is bifunctional or trifunctional with respect to a terminal hydroxy group, and that is free of a perfluoroalkyl group and a perfluoroalkylene group, a photoacid generator, and a solvent.

### BACKGROUND OF THE INVENTION

### Field of the Invention

The present disclosure relates to a method of producing a microstructure and a method of producing a liquid ejection head.

### Description of the Related Art

A liquid ejection head configured to eject a liquid is given as an example of a microstructure formed by using a photosensitive resin. The liquid ejection head is used in a liquid ejection apparatus, such as an ink jet recording apparatus, and includes a member having an ejection orifice and a flow path, and a substrate. The member having the ejection orifice and the flow path is arranged on the substrate. A supply port configured to supply the liquid to the flow path is formed in the substrate. The surface of the substrate on a side on which the flow path and the ejection orifice are arranged has an energy-generating element. The liquid is supplied from the supply port to the flow path, is given energy by the energy-generating element, and is ejected from the liquid ejection orifice to impinge on a recording medium, such as paper.

In many cases, an inorganic material layer is arranged on the substrate so as to serve as an insulating layer or a protective layer configured to cover the energy-generating element, or so as to be used for other various purposes. When the photosensitive resin serving as an organic material is used in the formation of the member having the ejection orifice and the flow path, the ejection orifice and the flow path can be formed by photolithography with high accuracy.

In Japanese Patent Application Laid-Open No. 2013-18272, there is a disclosure of a method of producing a liquid ejection head, the method including the steps of: forming a flow path wall forming layer from a negative photosensitive resin on a substrate having an inorganic material layer; exposing the layer to a flow path pattern; and then developing the layer to form a flow path wall.

In U.S. Pat. No. 8,500,246, there is a disclosure of a method of producing a liquid ejection head, the method including: transferring a dry film formed of a photosensitive resin onto the surface of a substrate having arranged therein the opening of a supply port penetrating the substrate and an energy-generating element by a lamination method; and processing the film by photolithography to form a flow path wall.

A microstructure such as a member of a liquid ejection head may be formed through the processing of a photosensitive resin layer serving as an organic material by photolithography. In this case, adhesiveness between the surface of a substrate having an inorganic material layer and the photosensitive resin layer serving as an organic material tends to be lower than that between organic material layers. When the photosensitive resin layer exposed to a microstructure pattern is treated with a developing liquid for a long time period at the time of the removal of an uncured portion from the photosensitive resin layer through development, in the case where the adhesiveness between the substrate and the photosensitive resin layer is not sufficient, peeling occurs therebetween. In Japanese Patent Application Laid-Open No. 2013-18272, at least three photosensitive resin layers are laminated on the substrate, and the three layers are exposed to a target microstructure pattern, followed by the performance of collective development. Accordingly, there may arise a need to sufficiently lengthen a development time. To further improve a production yield in such case, the adhesiveness between the photosensitive resin layer in contact with the substrate and the substrate is preferably strengthened.

Meanwhile, in U.S. Pat. No. 8,500,246, the flow path wall is formed by laminating the dry film formed of the photosensitive resin on the surface of the substrate having arranged therein the opening of the supply port, and processing the film. In such case, it is required that satisfactory adhesiveness be obtained between the dry film and the substrate, and no falling of the dry film into the opening of the supply port occur.

### SUMMARY OF THE INVENTION

According to at least one embodiment of the present disclosure, there is provided a method of producing a microstructure including: forming a resin layer from a photosensitive resin composition on a substrate; exposing the resin layer to a microstructure pattern to form a cured portion as a result of the exposure and an uncured portion as a result of non-exposure; and removing the uncured portion from the substrate through development to provide a microstructure pattern having the cured portion, wherein the photosensitive resin composition contains an epoxy resin, a crosslinking agent containing a polyhydric alcohol that is bifunctional or trifunctional with respect to a terminal hydroxy group, and that is free of a perfluoroalkyl group and a perfluoroalkylene group, a photoacid generator, and a solvent, wherein the polyhydric alcohol has a number-average molecular weight of less than 3,000, and wherein a surface of the substrate on which the resin layer is formed has one of unevenness and an opening.

Further features of the present invention will become apparent from the following description of exemplary embodiments with reference to the attached drawings.

### BRIEF DESCRIPTION OF THE DRAWINGS

FIG. 1A is a schematic perspective view for illustrating the configuration of a liquid ejection head.

FIG. 1B is a schematic sectional view taken along the line A-A′ of FIG. 1A.

FIG. 2A is a schematic sectional view for illustrating an example of a method of producing a dry film formed of a photosensitive resin composition.

FIG. 2B is a schematic sectional view for illustrating an example of the method of producing a dry film formed of a photosensitive resin composition.

FIG. 3A is a schematic sectional view for illustrating an example of a method of producing a liquid ejection head.

FIG. 3B is a schematic sectional view for illustrating an example of the method of producing a liquid ejection head.

FIG. 3C is a schematic sectional view for illustrating an example of the method of producing a liquid ejection head.

FIG. 3D is a schematic sectional view for illustrating an example of the method of producing a liquid ejection head.

FIG. 3E is a schematic sectional view for illustrating an example of the method of producing a liquid ejection head.

FIG. 3F is a schematic sectional view for illustrating an example of the method of producing a liquid ejection head.

FIG. 3G is a schematic sectional view for illustrating an example of the method of producing a liquid ejection head.

FIG. 3H is a schematic sectional view for illustrating an example of the method of producing a liquid ejection head.

FIG. 4A is a schematic sectional view for illustrating an example of a method of producing a liquid ejection head in Examples.

FIG. 4B is a schematic sectional view for illustrating an example of the method of producing a liquid ejection head in Examples.

FIG. 4C is a schematic sectional view for illustrating an example of the method of producing a liquid ejection head in Examples.

FIG. 4D is a schematic sectional view for illustrating an example of the method of producing a liquid ejection head in Examples.

FIG. 4E is a schematic sectional view for illustrating an example of the method of producing a liquid ejection head in Examples.

FIG. 4F is a schematic sectional view for illustrating an example of the method of producing a liquid ejection head in Examples.

FIG. 4G is a schematic sectional view for illustrating an example of the method of producing a liquid ejection head in Examples.

FIG. 4H is a schematic sectional view for illustrating an example of the method of producing a liquid ejection head in Examples.

FIG. 4I is a schematic sectional view for illustrating an example of the method of producing a liquid ejection head in Examples.

FIG. 4J is a schematic sectional view for illustrating an example of the method of producing a liquid ejection head in Examples.

FIG. 5A is a schematic sectional view for illustrating another example of the method of producing a liquid ejection head in Examples.

FIG. 5B is a schematic sectional view for illustrating another example of the method of producing a liquid ejection head in Examples.

FIG. 5C is a schematic sectional view for illustrating another example of the method of producing a liquid ejection head in Examples.

FIG. 5D is a schematic sectional view for illustrating another example of the method of producing a liquid ejection head in Examples.

FIG. 5E is a schematic sectional view for illustrating another example of the method of producing a liquid ejection head in Examples.

FIG. 5F is a schematic sectional view for illustrating another example of the method of producing a liquid ejection head in Examples.

FIG. 5G is a schematic sectional view for illustrating another example of the method of producing a liquid ejection head in Examples.

### DESCRIPTION OF THE EMBODIMENTS

An object of the present disclosure is to provide a method of producing a microstructure by which the strength of the microstructure such as a member having an ejection orifice and a flow path in a liquid ejection head, and adhesiveness between the member and a substrate can be improved.

An investigation by the inventors has found that, when film formation with a liquid composition and film formation with a dry film are compared to each other by using photosensitive resin compositions having the same composition, in the film formation involving using the dry film, an adhesive force between a cured product of the film and a substrate may be lower than that in the other film formation. The difference in adhesiveness is assumed to be due to a difference in wettability of the substrate at the time of the film formation.

The inventors have also found that, when the dry film is transferred onto a substrate having formed therein an opening while being heated and pressurized, in consideration of the stability of a pattern shape, the strength of the dry film needs to be improved for avoiding, for example, the falling of a resin into the opening portion at the time of the transfer. A possible approach to improving the strength of the dry film is to use a photosensitive resin having a large weight-average molecular weight. However, when the photosensitive resin having a large weight-average molecular weight is used for securing the heat resistance and pressure resistance of the dry film, the reactivity (crosslinking density) thereof may reduce to reduce the adhesiveness thereof with an inorganic material layer. Accordingly, for example, when a long time period is required for development as described in the foregoing, peeling between the inorganic material layer on a substrate side and an organic material layer formed of the cured portion of the photosensitive dry film may be remarkable.

Further, when ink having a high solvent ratio is used as a liquid to be flowed through a flow path, the peeling may similarly occur owing to long-term contact of the inorganic material layer with the ink. The inventors have further advanced an investigation, and as a result, have also found that the foregoing tendency becomes more remarkable depending on a material for the inorganic material layer on the substrate.

The problems in a method of producing a liquid ejection head involving using the dry film have been described above. However, the problems are common to microstructures formed from organic materials on inorganic material layers. For example, even when a photosensitive resin layer is applied onto a substrate by using a liquid photosensitive resin composition, and the resin layer (coated layer) is dried and then processed by photolithography, target adhesiveness may not be obtained between a member formed of a cured product of the photosensitive resin composition and the substrate.

The flow path forming member of a liquid ejection head is brought into a state of being always exposed to ink at the time of the use of the product. The ink to be typically used is often alkaline, and contains an organic solvent. When the volume swelling of the flow path forming member occurs owing to its constant contact with such substance, a flow path or an ejection orifice deforms, and hence a target ejection state is not obtained. Thus, the peeling of the flow path forming member from a substrate having an inorganic material layer occurs. Accordingly, the flow path forming member of the liquid ejection head is required to have swelling resistance. A possible approach to obtaining the swelling resistance is, for example, to use a resin excellent in low water absorptivity or a resin providing a high crosslinking density, or to increase the crosslinking density of the member through, for example, a change in process condition, such as an increase in exposure value or heat treatment temperature. However, it may be difficult to achieve both of: adhesiveness between the member and the inorganic material layer on a substrate side; and the accuracy of the pattern shape of a microstructure such as a flow path.

According to at least one embodiment of the present disclosure, the above-mentioned technical problems can be solved by using a photosensitive resin composition obtained by combining an epoxy resin with a specific polyhydric alcohol that functions as a crosslinking agent.

In at least one embodiment of the present disclosure, a photosensitive resin composition containing the following components (hereinafter referred to as “photosensitive resin composition (1)”) is used as a material for a resin layer for forming a microstructure such as a constituent member of a liquid ejection head on a substrate:

an epoxy resin;

a polyhydric alcohol that is bifunctional or trifunctional with respect to a terminal hydroxy group, that is free of a perfluoroalkyl group and a perfluoroalkylene group, and that has a number-average molecular weight of less than 3,000;

a photoacid generator; and

a solvent.

A method of producing a microstructure according to at least one embodiment of the present disclosure includes the following steps:

a step of forming a resin layer from a photosensitive resin composition (1) on a substrate;

a step of exposing the resin layer to a microstructure pattern to form a cured portion as a result of the exposure and an uncured portion as a result of non-exposure; and

a step of removing the uncured portion from the substrate through development to provide a microstructure pattern having the cured portion.

A method of producing a liquid ejection head including a substrate, and a member having an ejection orifice and a flow path according to at least one embodiment of the present disclosure includes the following steps:

a step of forming a resin layer from the photosensitive resin composition (1) on the substrate; and

a step of exposing and developing the resin layer on the substrate to form at least a portion having the flow path of the member having the ejection orifice and the flow path from a cured portion as a result of the exposure.

The surface of the substrate on which the resin layer formed from the photosensitive resin composition (1) is arranged may have unevenness or an opening, or may have an inorganic material layer. In each of the production methods, even in any such case, satisfactory adhesiveness can be obtained between a portion formed of a cured product of the photosensitive resin composition (1) and the substrate.

In each of the methods, the following methods may each be used in the formation of the resin layer from the photosensitive resin composition (1) on the substrate:

a method including the steps of: applying the photosensitive resin composition (1) to the substrate to form a coated layer; and drying the coated layer; and

a method including the steps of: applying the photosensitive resin composition (1) onto a base material to provide a coated layer; forming a dry film from the coated layer; and transferring the dry film from the base material onto the substrate.

A method of producing the liquid ejection head including the following respective steps may be used in accordance with the form of the member having the ejection orifice and the flow path in the liquid ejection head.

(i) First Mode in which Member Having Ejection Orifice and Flow Path has Flow Path Forming Member and Ejection Orifice Forming Member

A method including:

a step of arranging a first resin layer from the photosensitive resin composition (1) on the substrate;

a step of forming a flow path pattern on the first resin layer arranged on the substrate through exposure;

a step of arranging a second resin layer having photosensitivity on the first resin layer having formed thereon the flow path pattern;

a step of forming an ejection orifice pattern on the second resin layer through exposure;

a step of developing the first resin layer having formed thereon the flow path pattern to form the flow path forming member; and

a step of developing the second resin layer having formed thereon the ejection orifice pattern to form the ejection orifice forming member.

In the method, the first resin layer and the second resin layer may be collectively developed.

(ii) Second Mode in which Ejection Orifice and Flow Path are Arranged in Common Member

A method including:

a step of arranging a mold material having a flow path pattern on the substrate;

a step of covering the mold material on the substrate with a photosensitive resin layer through the use of the photosensitive resin composition (1);

a step of exposing the resin layer to an ejection orifice pattern;

a step of developing the resin layer having arranged thereon the ejection orifice pattern to form the member having the ejection orifice and the flow path, the member being formed of the cured portion of the resin layer; and

a step of removing the mold material from the substrate.

In the method, the step of forming the member having the ejection orifice and the flow path through the development, and the step of removing the mold material from the substrate may be collectively performed.

A preferred embodiment in the above-mentioned first mode is described below with reference to the drawings. In the following description, a case in which the method of producing a microstructure according to at least one embodiment of the present disclosure is applied to the production of a liquid ejection head is described as an example. However, the method of producing a microstructure according to at least one embodiment of the present disclosure is not limited to the application to the production of a liquid ejection head. In addition, in the following description, the same number is given to configurations having the same function in the drawings, and their description may be omitted.

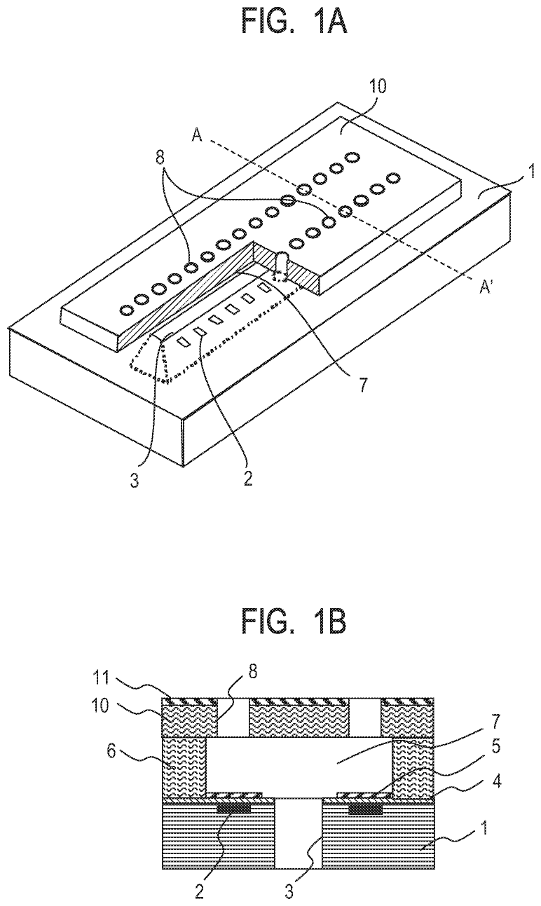

FIG. 1A is a schematic perspective view for illustrating a liquid ejection head according to at least one embodiment of the present disclosure. In addition, FIG. 1B is a schematic sectional view of the liquid ejection head according to at least one embodiment of the present disclosure viewed from a surface perpendicular to its substrate, the surface passing a line A-A′ in FIG. 1A.

The liquid ejection head illustrated in each of FIG. 1A and FIG. 1B includes a substrate 1 in which energy-generating elements 2 configured to generate energy for ejecting a liquid are formed at predetermined pitches. Examples of the energy-generating elements 2 include an electrothermal conversion element and a piezoelectric element. The energy-generating elements 2 may be arranged so as to be in contact with the surface of the substrate 1, or may be arranged so as to be partially hollow with respect to the surface of the substrate 1. Control signal input electrodes (not shown) for operating the energy-generating elements 2 are connected to the energy-generating elements 2. In addition, the substrate 1 has opened therein a supply port 3 configured to supply ink.

An inorganic material layer 4 and a protective layer 5 are formed on the first surface side of the substrate 1 on which the energy-generating elements 2 are arranged.

The substrate 1 is, for example, a silicon substrate formed of silicon. The silicon substrate is preferably a silicon single crystal whose surface has a crystal orientation of (100).

As a material for forming the inorganic material layer 4, there are given, for example, silicon oxide (SiO₂), silicon nitride (SiN), silicon carbide (SiC), silicon carbonitride (SiCN), and silicon oxycarbide (SiOC). In each of FIG. 1A and FIG. 1B, the inorganic material layer 4 is used as a heat storage layer or an insulating layer.

The protective layer 5 protects the energy-generating elements, and is formed of, for example, Ta or Ir. The inorganic material layer 4 may cover the energy-generating elements.

In each of FIG. 1A and FIG. 1B, the inorganic material layer 4 is formed on substantially the entire surface of the substrate 1.

A member having ejection orifices and a flow path in this embodiment has a flow path forming member 6 and an ejection orifice forming member 10, and the flow path forming member is illustrated under a state of being integrated with the ejection orifice forming member 10 in FIG. 1A.

The side walls of a flow path 7 are formed by the flow path forming member 6 on the inorganic material layer 4. Further, the ejection orifice forming member 10 having ejection orifices 8 is formed on the flow path forming member 6 and the flow path 7. In addition, a liquid repellent layer 11 is formed on the ejection orifice forming member 10 as required.

The liquid ejection head ejects the ink supplied from the supply port 3 through the flow path 7 as ink droplets from the ejection orifices 8 through the flow path 7 by applying a pressure generated by the energy-generating elements 2 to the ink.

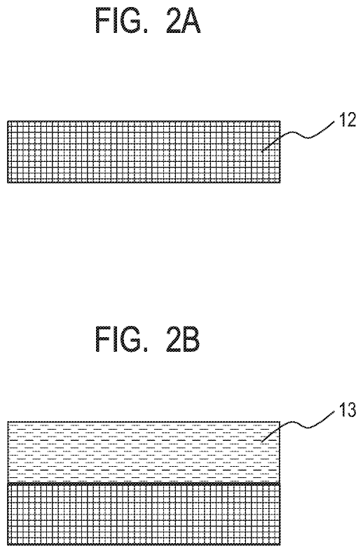

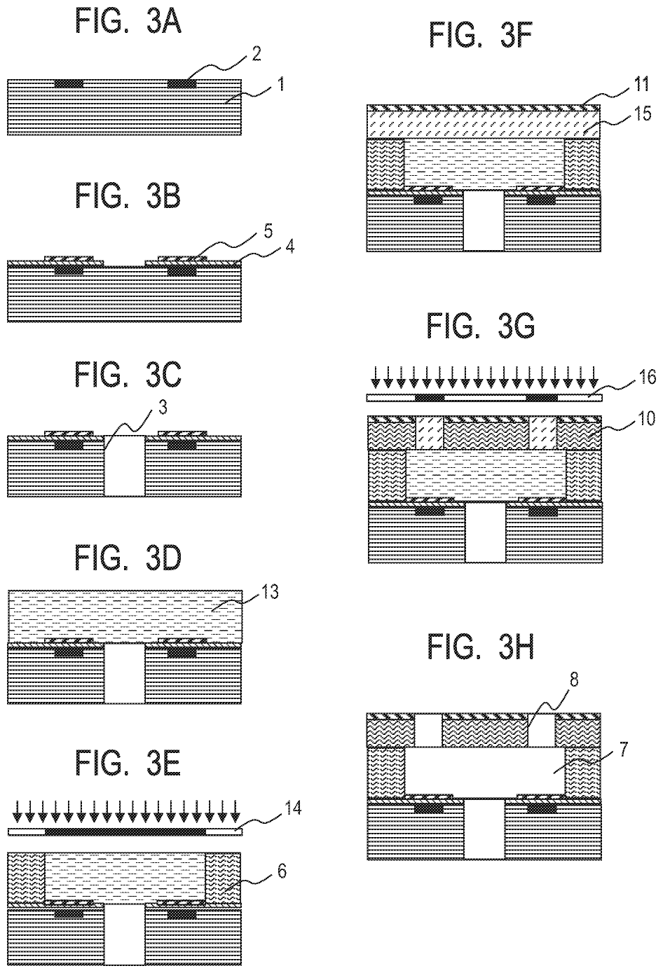

Next, an example of the method of producing a liquid ejection head according to the above-mentioned first mode is described below with reference to FIG. 2A and FIG. 2B, and FIG. 3A to FIG. 3H.

FIG. 2A and FIG. 2B are each a view for illustrating an example of a method of producing a dry film formed of the photosensitive resin composition (1).

FIG. 3A to FIG. 3H are each a schematic sectional view for illustrating an example of the method of producing a liquid ejection head, and are each a view when the head is viewed under a completed state at the same sectional position as that of FIG. 1B.

First, as illustrated in FIG. 2A, a film base material 12 formed of, for example, a polyethylene terephthalate (PET) or a polyimide is prepared. Next, as illustrated in FIG. 2B, the photosensitive resin composition (1) is applied onto the film base material 12 by, for example, a spin coating method or a slit coating method to form a coated layer. When the coated layer is prebaked to be dried, a dry film 13 can be produced from the photosensitive resin composition (1). The photosensitive resin composition (1) contains an epoxy resin having a weight-average molecular weight of more than 5,000, a polyhydric alcohol that is bifunctional or trifunctional with respect to a terminal hydroxy group, and that is free of a perfluoroalkyl group and a perfluoroalkylene group, a photoacid generator, and a solvent, and has negative photosensitivity.

Details about the respective components and composition of the photosensitive resin composition (1) are described later.

The thickness of the dry film 13 corresponds to the height of the flow path, and is hence appropriately determined by the ejection design of the liquid ejection head; the thickness is preferably set to, for example, 3 μm or more and 45 μm or less.

Next, as illustrated in FIG. 3A, the substrate 1 having the energy-generating elements 2 on its first surface side is prepared.

Next, as illustrated in FIG. 3B, the inorganic material layer 4 is formed on the surface side of the substrate 1 so as to cover the energy-generating elements 2. In addition, the protective layer 5 is formed above the energy-generating elements 2. The inorganic material layer 4 and the protective layer 5 are subjected to patterning as required.

Next, as illustrated in FIG. 3C, the supply port 3 that penetrates the substrate 1 and is configured to supply the ink is formed. The supply port 3 is formed at a desired position by using wet etching with an alkaline etching liquid, such as tetramethylammonium hydroxide (TMAH), or dry etching, such as reactive ion etching.

Next, as illustrated in FIG. 3D, the dry film 13 produced in FIG. 2A and FIG. 2B is transferred onto the inorganic material layer 4 of the substrate 1 having arranged therein the energy-generating elements 2 and the supply port 3 by using a lamination method to be formed as a first resin layer. In the case of a substrate in which the supply port 3 is not arranged, the film formation may be performed through the application of the photosensitive resin composition (1) by, for example, a spin coating method or a slit coating method without turning the composition into a dry film.

Next, as illustrated in FIG. 3E, the dry film 13 is selectively exposed to a flow path pattern through a photomask 14 having the flow path pattern. Further, a heat treatment (post exposure baking) is performed to cure the exposed portion of the film. Thus, the flow path forming member 6 is formed. A non-exposed portion in the dry film 13 is left as an uncured portion.

The photomask 14 is obtained by forming a light-shielding film, such as a chromium film, on a substrate formed of a material that transmits light having an exposure wavelength, such as glass or quartz, in accordance with the pattern of the flow path or the like. A projection exposure apparatus having a light source having a single wavelength, such as an i-line exposure stepper or a KrF stepper, or a projection exposure apparatus having a broad-wavelength mercury lamp as a light source, such as MASK ALIGNER MPA-600 Super (product name, manufactured by Canon Inc.), may be used as an exposure apparatus.

Next, a photosensitive resin composition (2) is applied to a film base material formed of, for example, a PET or a polyimide, and is then turned into a dry film 15. The film is transferred onto the dry film 13 subjected to the exposure treatment by using a lamination method to be formed as a second resin layer.

Further, the liquid repellent layer 11 is formed on the dry film 15 as required. The dry film 15 serving as the ejection orifice forming member 10 is preferably formed of a cationically polymerizable epoxy resin composition in consideration of, for example, its adhesiveness with the flow path forming member 6, mechanical strength, stability against a liquid such as ink, and resolution. In addition, the thickness of the dry film 15 is appropriately determined by the ejection design of the liquid ejection head, and is hence not particularly limited. However, the thickness is preferably set to, for example, 3 μm or more and 25 μm or less from the viewpoint of the mechanical strength or the like.

The liquid repellent layer 11 is required to have liquid repellency against a liquid such as ink, and a perfluoroalkyl composition or perfluoropolyether composition having cationic polymerizability is preferably used in the formation of the liquid repellent layer 11. It has been generally known that the fluorinated alkyl chain of the perfluoroalkyl composition or the perfluoropolyether composition is unevenly distributed to an interface between the composition and air by a baking treatment after its application. Accordingly, the liquid repellency of the surface of the composition can be improved.

Next, as illustrated in FIG. 3G, the dry film 15 and the liquid repellent layer 11 are subjected to pattern exposure through a photomask 16 having an ejection orifice pattern. Further, a heat treatment (post exposure baking) is performed to cure the exposed portions of the film and the layer. Thus, the ejection orifice forming member 10 is formed. When the dry film 15 is exposed to light having the same wavelength as that of the light to be used in the exposure of the dry film 13, an exposure value for curing the dry film 15 needs to be made smaller than an exposure value for curing the dry film 13. In other words, when the quantity of the light that has passed the dry film 15 at the time of the exposure of the dry film 15 is the exposure value for curing the dry film 13, it becomes difficult to remove the non-exposed portion of the dry film 13 in a developing step to be described later, and hence the flow path 7 cannot be formed. In view of the foregoing, the dry film 15 needs to have sensitivity relatively higher than that of the dry film 13.

The photomask 16 is obtained by forming a light-shielding film, such as a chromium film, on a substrate formed of a material that transmits light having an exposure wavelength, such as glass or quartz, in accordance with the ejection orifice pattern. A projection exposure apparatus having a light source having a single wavelength, such as an i-line exposure stepper or a KrF stepper, or a projection exposure apparatus having a broad-wavelength mercury lamp as a light source, such as MASK ALIGNER MPA-600 Super (product name, manufactured by Canon Inc.), may be used as an exposure apparatus.

Next, the uncured portions of the dry film 13, the dry film 15, and the liquid repellent layer 11 are developed with a developing liquid to be collectively removed. Thus, as illustrated in FIG. 3H, the flow path 7 and the ejection orifices 8 are formed. A heat treatment is performed as required to complete the liquid ejection head.

Examples of the developing liquid include propylene glycol monomethyl ether acetate (PGMEA), methyl isobutyl ketone (MIBK), and xylene. In addition, a rinsing treatment using isopropyl alcohol (IPA) or the like may be performed as required.

In the above-mentioned production method, the dry film 15 is laminated on the dry film 13 after the exposure of the dry film 13. However, the exposure treatment may be performed after the dry film 15 has been laminated before the exposure of the dry film 13.

In addition, in the above-mentioned production method, the flow path forming member 6 and the ejection orifice forming member 10 are formed by using two layers. However, the present disclosure is not limited to the mode. The respective members may be formed by using three or more photosensitive resins.

The photosensitive resin compositions (1) and (2) are described below.

Each of the photosensitive resin compositions to be used in the formation of the member having the ejection orifices and the flow path preferably contains a cationically polymerizable epoxy resin in consideration of, for example, the adhesive performance, mechanical strength, liquid (ink) resistance, swelling resistance, reactivity as a photolithography material, and resolution of a cured product thereof. Specific examples thereof may include cationically polymerizable epoxy resins, such as polyfunctional epoxy resins including: epoxy resins each having a bisphenol skeleton, such as a bisphenol A-type epoxy resin and a bisphenol F-type epoxy resin; epoxy resins each having a phenol novolac skeleton, such as a phenol novolac-type epoxy resin; epoxy resins each having a cresol novolac skeleton, such as a cresol novolac-type epoxy resin; epoxy resins each having a norbornene skeleton; epoxy resins each having a terpene skeleton; epoxy resins each having a dicyclopentadiene skeleton; and epoxy resins each having an oxycyclohexane skeleton. Those epoxy resins may be used alone or in combination thereof.

A photocationically polymerizable epoxy resin composition may be prepared by adding a cationic initiator to each of the photosensitive resin compositions.

In addition, the use of an epoxy resin having two or more epoxy groups is suitable for obtaining desired characteristics because a cured product of each of the photosensitive resin compositions is three-dimensionally crosslinked.

When the dry film 13 in an uncured state is transferred onto the inorganic material layer 4 arranged on the substrate 1 under heating, the dry film 13 is required to have heat resistance in consideration of the stability of a target pattern shape. In addition, the dry film 13 needs to have such film strength that, even when the dry film 13 in an uncured state is transferred onto the surface of a substrate having an opening or a depressed portion while heat is applied thereto, or when the film is in an uncured state at the time of any other thermal step, such as a heat treatment after its exposure, the layer does not deform. When the strength of the dry film 13 in an uncured state or the strength of the uncured portion of the dry film 13 after its selective exposure is high, the falling of the uncured portion of the dry film 13 into the opening of the supply port 3 of the substrate 1 in, for example, a treating step under heating can be effectively suppressed. Therefore, the height of the flow path can be stably obtained.

Accordingly, the epoxy resin serving as a resin component of the photosensitive resin composition (1) preferably contains an epoxy resin having a high weight-average molecular weight (Mw). The weight-average molecular weight of the high-weight-average molecular weight epoxy resin is preferably 5,000 or more, and is more preferably 100,000 or less. In addition, the softening point of the high-weight-average molecular weight epoxy resin is preferably 90° C. or more for more effectively preventing the falling of the uncured portion.

Further, at least one kind of bifunctional epoxy resin is preferably used as the high-weight-average molecular weight epoxy resin for the photosensitive resin composition (1). Further, at least one kind of epoxy resin that is trifunctional or more may be added to the bifunctional epoxy resin before use.

The incorporation of a resin having three or more epoxy groups allows the crosslinking of the photosensitive resin composition to three-dimensionally advance, and hence can improve the sensitivity thereof as a photosensitive material. The epoxy equivalent of the epoxy resin that is trifunctional or more is preferably less than 500. When the epoxy equivalent is 500 or more, the sensitivity is insufficient, and hence a reduction in pattern resolution, or a reduction in mechanical strength or adhesiveness of a cured product of the composition may occur.

The weight-average molecular weight (Mw) of any such resin may be calculated by a known method involving using a gel permeation chromatography apparatus (manufactured by, for example, Shimadzu Corporation) in terms of polystyrene. In addition, the molecular weight (number-average molecular weight) of the polyhydric alcohol of the photosensitive resin composition may be determined by a known method.

The photosensitive resin composition (1) contains, as a crosslinking agent, the polyhydric alcohol that is bifunctional or trifunctional with respect to a terminal hydroxy group from the viewpoint of its adhesiveness with the inorganic material layer. The addition of the polyhydric alcohol having hydroxy groups at its terminals enables: the acceleration of the cationic polymerization reaction of the epoxy resin; and a reduction in stress of a resin cured product by a reaction between a ring-opened epoxy group and a hydroxy group. Therefore, the alcohol is effective in improving the adhesiveness with the inorganic material layer.

The epoxy resin serving as a component of the photosensitive resin composition (2) preferably contains an epoxy resin that is trifunctional or more, and may contain a bifunctional epoxy resin listed in the foregoing in addition to the epoxy resin that is trifunctional or more. The weight-average molecular weight (Mw) of the epoxy resin that is trifunctional or more is preferably 500 or more and 4,000 or less.

A polyhydric alcohol serving as a crosslinking agent is not essential to the photosensitive resin composition (2), but the composition may contain a polyhydric alcohol serving as a crosslinking agent as required.

The functional groups of the polyhydric alcohol are terminal hydroxy groups, and a polyhydric alcohol that is bifunctional or trifunctional with respect to the number of the hydroxy groups is used. Specifically, when the number of the terminal hydroxy groups is less than 2, an accelerating effect on the cationic polymerization reaction of the epoxy resin is small, and when the number is 4 or more, the adhesiveness of the photosensitive resin composition with the inorganic material layer at the time of the contact thereof with a solvent or ink reduces. In view of the foregoing, a polyhydric alcohol having 2 or 3 terminal hydroxy groups is used.

Further, the polyhydric alcohol is free of a perfluoroalkyl group and a perfluoroalkylene group. The presence of a perfluoroalkyl group and a perfluoroalkylene group unevenly distributes the alcohol toward an air interface after film formation to reduce an improving effect on the adhesiveness with the inorganic material layer. In addition, when the photosensitive resin composition (1) is used as a dry film, the polyhydric alcohol containing a perfluoroalkyl group and a perfluoroalkylene group, the alcohol being unevenly distributed to the surface of the composition in contact with the inorganic material layer, is present in a large amount. As a result, a reduction in adhesiveness with the inorganic material layer occurs. Further, the number-average molecular weight of the polyhydric alcohol is set to less than 3,000 for improving the resolution of the composition as a photolithography material through an improvement in adhesiveness by the maintenance of the ratio of a hydroxy group equivalent in a molecule thereof.

In addition, in order that the polyhydric alcohol may not disappear in a heating step before the developing step, such as prebaking or PEB, the alcohol preferably has a boiling point higher than the heating temperature.

Preferred examples of the polyhydric alcohol may include the following two kinds of polyhydric alcohols:

a high-molecular weight and bifunctional or trifunctional polyhydric alcohol having a number-average molecular weight of 200 or more and less than 3,000, and having a repeating structure in a molecule thereof; and

a bifunctional or trifunctional and low-molecular weight polyhydric alcohol having a number-average molecular weight of less than 200 and a boiling point of 200° C. or more.

At least one kind of polyhydric alcohol selected from those polyhydric alcohols may be used.

Examples of the high-molecular weight polyhydric alcohol may include compounds represented by the following formulae (a) to (c). At least one of those compounds may be used.

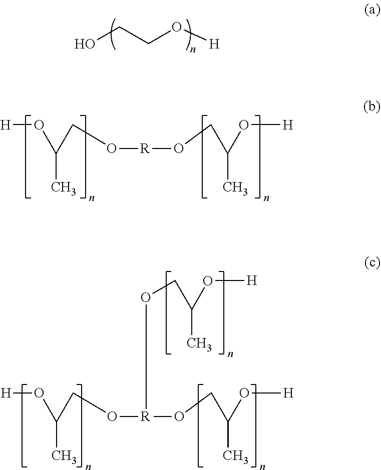

In the formulae, respective “n”s each independently represent a natural number, and respective Rs each independently represent an aliphatic group that may have an oxygen atom and/or a nitrogen atom, and that may be cyclic, or an aromatic group that may have an oxygen atom, and each have 1 to 15 carbon atoms.

Examples of the compound represented by the formula (a) may include polyethylene glycols (200, 300, 400, 600, 1000, and 2000) commercially available from various manufacturers.

Examples of the compounds represented by the formulae (b) and (c) may include polyether polyols, specifically ADEKA Polyether P series, BPX series, G series, SP series, SC series, CM series, AM series, EM series, BM series, PR series, and GR series (product name) manufactured by ADEKA Corporation.

Examples of the low-molecular weight polyhydric alcohol may include at least one selected from the group consisting of 1,2-hexanediol, 1,6-hexanediol, glycerin, trimethylolpropane, 3-methyl-1,5-pentanediol, 1,2,6-hexanetriol, 1,5-dihydroxypentan-3-one, 6-hydroxycaproic acid, and 2-hydroxymethyl-1,3-propanediol. At least one kind of those compounds may be used.

The addition amount of the polyhydric alcohol is preferably 0.5% or more and 30.0% or less, more preferably 1.0% or more and 10.0% or less with respect to the entire mass of the epoxy resin in the photosensitive resin composition (1) from the viewpoints of an improvement in adhesiveness of the composition with the inorganic material layer and an improvement in resolution thereof as a photolithography material.

An epoxy resin selected from commercial epoxy resins and known epoxy resins may be used in the preparation of each of the photosensitive resin composition (1) serving as the flow path forming member and the photosensitive resin composition (2) serving as the ejection orifice forming member.

Examples of the commercial bifunctional epoxy resin having a weight-average molecular weight of 5,000 or more include: “jER1004”, “jER1007”, “jER1009”, “jER1010”, and “jER1256” (product name) manufactured by Mitsubishi Chemical Corporation; and “EPICLON 4050” and “EPICLON 7050” (product name) manufactured by Dainippon Ink and Chemicals, Inc.

Examples of the commercial epoxy resin that is trifunctional or more include: “CELLOXIDE 2021”, “GT-300 series”, “GT-400 series”, and “EHPE3150” (product name) manufactured by Daicel Chemical Industries, Ltd.; “jER1031S” and “157S70” (product name) manufactured by Mitsubishi Chemical Corporation; and “EPICLON N-695”, “EPICLON N-865”, “EPICLON HP-6000”, “EPICLON HP-4710”, “EPICLON HP-7200 series”, and “EPICLON EXA-4816” (product name) manufactured by Dainippon Ink and Chemicals, Inc.

A photopolymerization initiator to be added to the resin composition is preferably a sulfonic acid compound, a diazomethane compound, a sulfonium salt compound, an iodonium salt compound, a disulfone-based compound, or the like. Examples of commercial products thereof include: “ADEKA Optomer SP-170”, “ADEKA Optomer SP-172”, and “SP-150” (product name) manufactured by ADEKA Corporation; “BBI-103” and “BBI-102” (product name) manufactured by Midori Kagaku Co., Ltd.; “IBPF”, “IBCF”, “TS-01”, and “TS-91” (product name) manufactured by Sanwa Chemical Co., Ltd.; “CPI-210”, “CPI-300”, and “CPI-410” (product name) manufactured by San-Apro Ltd.; and “Irgacure 290” (product name) manufactured by BASF Japan. Those photoacid generators may be used as a mixture thereof.

Further, a silane coupling agent may be added for the purpose of increasing the adhesive performance. A commercial silane coupling agent is, for example, “A-187” (product name) manufactured by Momentive Performance Materials Inc.

In addition, a sensitizer such as an anthracene compound, a basic substance, such as an amine, an acid generator that generates toluenesulfonic acid that is weakly acidic (pKa=−1.5 to 3.0), or the like may be added for improving the pattern resolution or adjusting the sensitivity of each of the photosensitive resin compositions (exposure value needed for its curing). A commercial acid generator that generates toluenesulfonic acid is, for example, “TPS-1000” (product name) manufactured by Midori Kagaku Co., Ltd., or “WPAG-367” (product name) manufactured by Wako Pure Chemical Industries, Ltd.

In addition, for example, “SU-8 series” and “KMPR-1000” (product name) manufactured by Kayaku MicroChem Corporation, and “TMMR 52000” and “TMMF S2000” (product name) manufactured by Tokyo Ohka Kogyo Co., Ltd. commercially available as negative resists may each be used as the photosensitive resin composition (2).

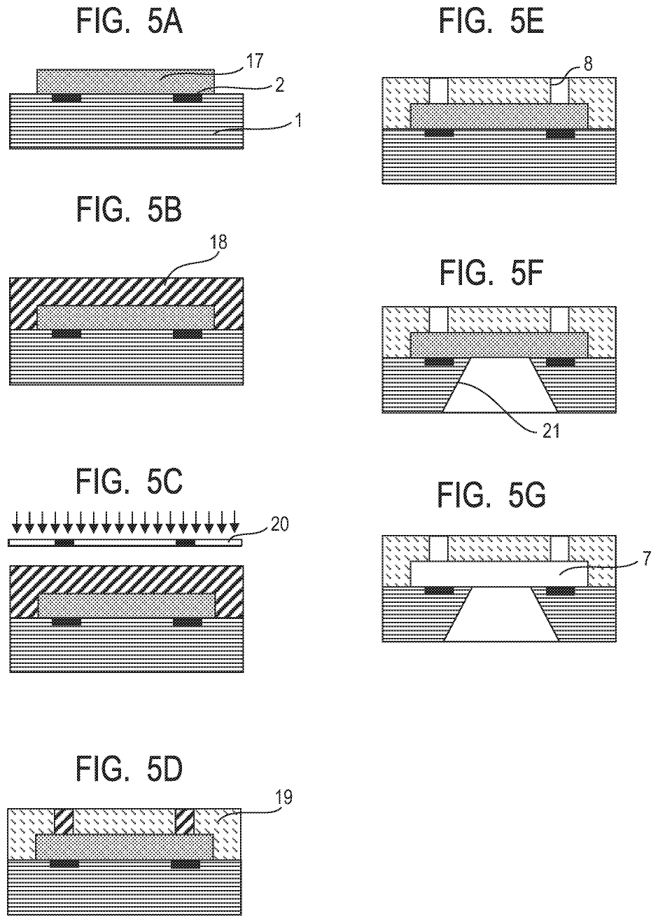

Next, an example of the method of producing a liquid ejection head according to the second mode in which the flow path and the ejection orifices described in the foregoing are formed in a common member is described with reference to FIG. 5A to FIG. 5G.

First, a resin layer is formed from a positive photosensitive resin serving as a mold material for the flow path 7 on the surface of the substrate 1 on which the energy-generating elements 2, the inorganic material layer (not shown), and the like have been arranged. The resin layer is exposed to a flow path pattern through exposure, and its exposed portion is developed to be removed. Thus, as illustrated in FIG. 5A, a mold material 17 is formed.

Next, as illustrated in FIG. 5B, the photosensitive resin composition (1) is applied for forming a member 19 having ejection orifices and a flow path. Thus, a negative photosensitive resin layer 18 covering the mold material 17 is formed. As illustrated in FIG. 5C, the negative photosensitive resin layer 18 is selectively exposed to light through a photomask 20 so that portions where the ejection orifices 8 are formed may be non-exposed portions. Thus, as illustrated in FIG. 5D, the member 19 having the flow path and the ejection orifices is formed. Further, the negative photosensitive resin layer 18 subjected to the exposure treatment is developed with a developing liquid. Thus, as illustrated in FIG. 5E, the ejection orifices 8 are formed.

Next, as illustrated in FIG. 5F, the substrate 1 is subjected to anisotropic etching with an etching liquid through the use of a resin layer having resistance to the etching liquid as an etching mask. Thus, a supply port 21 is formed.

After that, as illustrated in FIG. 5G, the mold material 17 is dissolved and removed, and the flow path 7 is formed by immersing the substrate 1 in a dissolving liquid for the mold material.

The ejection orifices 8 and the flow path 7 may be collectively formed by utilizing the same treatment liquid as the developing liquid for forming the ejection orifices 8 and the dissolving liquid for removing the mold material 17.

The photosensitive resin composition (1) according to this mode contains an epoxy resin, a crosslinking agent containing a polyhydric alcohol that is bifunctional or trifunctional with respect to a terminal hydroxy group, and that is free of a perfluoroalkyl group and a perfluoroalkylene group, a photoacid generator, and a solvent.

The epoxy resins listed in the above-mentioned first mode may each be similarly used as the epoxy resin. In this mode, the epoxy resin preferably contains any one of the epoxy resins that are trifunctional or more, the resins being listed in the above-mentioned first mode, and the bifunctional epoxy resins listed in the above-mentioned first mode may each be added as required.

The high-molecular weight polyhydric alcohols listed in the above-mentioned first mode may each be preferably used as the crosslinking agent.

Those listed in the above-mentioned first mode may be similarly utilized as the photoacid generator and the solvent.

### EXAMPLES

The present disclosure is described in more detail below by way of Examples. However, the present disclosure is not limited to these Examples.

The following products were used as components described by product names in Examples and Comparative Examples described below.

EPICLON N695 (product name, manufactured by Dainippon Ink and Chemicals, Inc., epoxy resin that is trifunctional or more) (Mw: 3,400)

157S70 (product name, manufactured by Mitsubishi Chemical Corporation, epoxy resin that is trifunctional or more) (Mw: 3,300)

EHPE-3150 (product name, manufactured by Daicel Chemical Industries, Ltd., epoxy resin that is trifunctional or more) (Mw: 3,000)

EPICLON HP7200H (product name, manufactured by Dainippon Ink and Chemicals, Inc., epoxy resin that is trifunctional or more) (Mw: 2,400)

jER1001 (product name, manufactured by Mitsubishi Chemical Corporation, bifunctional epoxy resin) (Mw: 3,030)

jER1007 (product name, manufactured by Mitsubishi Chemical Corporation, bifunctional epoxy resin) (Mw: 11,200)

jER1009 (22,700) (product name, manufactured by Mitsubishi Chemical Corporation, bifunctional epoxy resin) (Mw: 22,700)

jER1256 (58,000) (product name, manufactured by Mitsubishi Chemical Corporation, bifunctional epoxy resin) (Mw: 58,000)

PEG200 (product name, manufactured by Sanyo Chemical Industries, Ltd., polyethylene glycol)

PEG600 (product name, manufactured by Sanyo Chemical Industries, Ltd., polyethylene glycol)

PEG1000 (product name, manufactured by Sanyo Chemical Industries, Ltd., polyethylene glycol)

PEG3000 (product name, manufactured by Sigma-Aldrich, polyethylene glycol)

Polyether polyol: diol (manufactured by ADEKA Corporation, P-1000 (product name)) (molecular weight: 1,000)

Polyether polyol: triol (manufactured by ADEKA Corporation, G-1500 (product name)) (molecular weight: 1,500)

Polyether polyol: tetraol (manufactured by ADEKA Corporation, BM-54 (product name)) (molecular weight: 500)

CPI-4105 (product name, manufactured by San-Apro Ltd., cationic polymerization initiator)

SP-172 (“ADEKA Optomer SP-172”, product name, manufactured by ADEKA Corporation, cationic polymerization initiator)

TPS-1000 (product name, manufactured by Midori Kagaku Co., Ltd., acid generator)

A-187 (product name, manufactured by Momentive Performance Materials Inc., silane coupling agent)

ACETYLENOL (ACETYLENOL E100, product name, manufactured by Kawaken Fine Chemicals Co., Ltd., ethylene oxide adduct of acetylene glycol)

The following compounds have the following molecular weights.

1,6-Hexane diol (molecular weight: 118.18)

Trimethylolpropane (molecular weight: 134.18)

Butanol (molecular weight: 89.14)

1,4-Bis(hexafluoro-2-propyl)benzene [1,4-HFAB] (molecular weight: 410)

### Examples 1 to 22

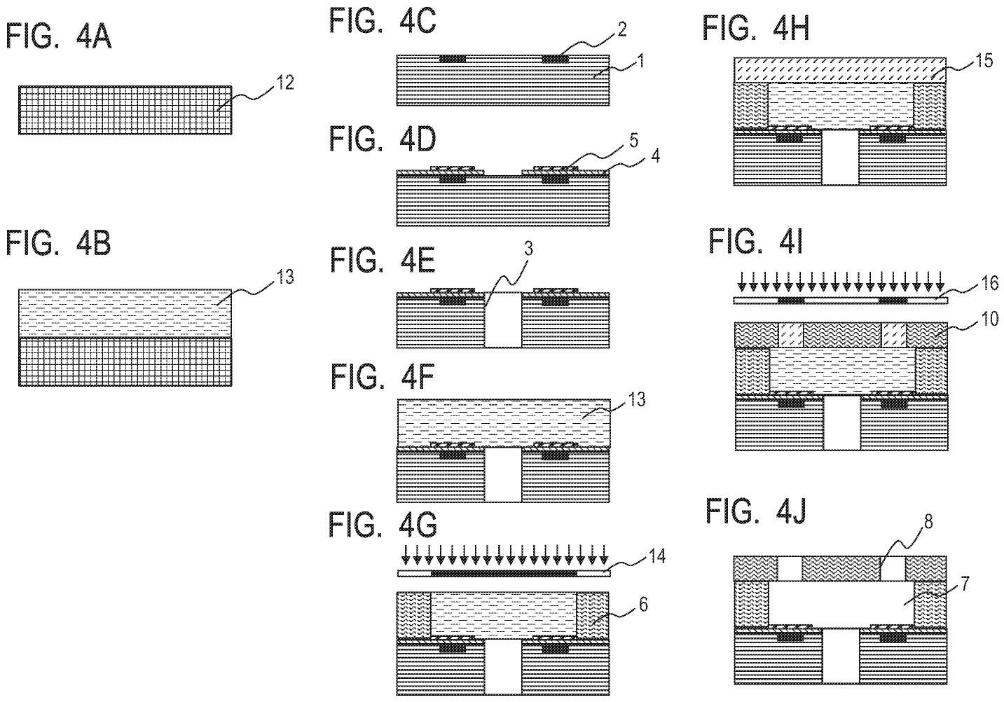

A liquid ejection head was produced through steps illustrated in FIG. 4A to FIG. 4J by individually using each of the photosensitive resin compositions (1) shown in Table 1-1 to Table 1-3 for each of Examples. In each table, composition is represented by “part(s) by mass”.

TABLE 1-1
Photosensitive resin composition (1)

| | | Example | | | | | | | |
|---|---|---|---|---|---|---|---|---|---|
| Component | Product name | 1 | 2 | 3 | 4 | 5 | 6 | 7 | 8 |
| Epoxy resin that is | EPICLON N695 | 100 | 100 | 100 | 100 | 100 | 100 | 100 | 100 |
| trifunctional or more | | | | | | | | | |
| Bifunctional epoxy | jER1001 (3,030) | — | — | — | — | — | — | — | — |
| resin (weight- | jER1007 (11,200) | 50 | 50 | 50 | 50 | 50 | 50 | 50 | 50 |
| average molecular | jER1009 (22,700) | — | — | — | — | — | — | — | — |
| weight Mw) | jER1256 (58,000) | — | — | — | — | — | — | — | — |
| Additive | PEG200 | 2.5 | 5 | | | | | | |
| | PEG600 | | | 1 | 2.5 | 5 | 10 | 30 | |
| | PEG1000 | | | | | | | | 5 |
| | Trimethylolpropane | | | | | | | | |
| | 1,6-Hexanediol | | | | | | | | |
| | Polyether polyol: diol | | | | | | | | |
| | Polyether polyol: triol | | | | | | | | |
| Photoacid generator | CPI-410S | 1.5 | 1.5 | 1.5 | 1.5 | 1.5 | 1.5 | 1.5 | 1.5 |
| | SP-172 | 3.3 | 3.3 | 3.3 | 3.3 | 3.3 | 3.3 | 3.3 | 3.3 |
| Acid generator | TPS-1000 | 0.5 | 0.5 | 0.5 | 0.5 | 0.5 | 0.5 | 0.5 | 0.5 |
| Silane coupling agent | A-187 | 5.0 | 5.0 | 5.0 | 5.0 | 5.0 | 5.0 | 5.0 | 5.0 |
| Solvent | PGMEA | 120 | 120 | 120 | 120 | 120 | 120 | 120 | 120 |

TABLE 1-2
Photosensitive resin composition (1)

| | | Example | | | | | | | |
|---|---|---|---|---|---|---|---|---|---|
| Component | Product name | 9 | 10 | 11 | 12 | 13 | 14 | 15 | 16 |
| Epoxy resin that is | EPICLON N695 | 100 | 100 | 100 | 100 | 100 | 100 | 100 | 100 |
| trifunctional or more | | | | | | | | | |
| Bifunctional epoxy | jER1001 (3,030) | — | — | — | — | — | — | — | — |
| resin (weight- | jER1007 (11,200) | 50 | 50 | 30 | — | — | 50 | 50 | 50 |
| average molecular | jER1009 (22,700) | — | — | — | 20 | — | — | — | — |
| weight Mw) | jER1256 (58,000) | — | — | — | — | 10 | — | — | — |
| Additive | PEG200 | | | | | | | | |
| | PEG600 | | | 2.5 | 2.5 | 2.5 | | | |
| | PEG1000 | | | | | | | | |
| | Trimethylolpropane | 10 | | | | | | | |
| | 1,6-Hexanediol | | 10 | | | | | | |
| | Polyether polyol: diol | | | | | | 5 | | |
| | Polyether polyol: triol | | | | | | | 5 | 10 |
| Photoacid generator | CPI-410S | 1.5 | 1.5 | 1.5 | 1.5 | 1.5 | 1.5 | 1.5 | 1.5 |
| | SP-172 | 3.3 | 3.3 | 3.0 | 4.0 | 5.8 | 3.3 | 3.3 | 3.3 |
| Acid generator | TPS-1000 | 0.5 | 0.5 | 0.4 | 0.5 | 0.6 | 0.5 | 0.5 | 0.5 |
| Silane coupling agent | A-187 | 5.0 | 5.0 | 5.0 | 5.0 | 5.0 | 5.0 | 5.0 | 5.0 |
| Solvent | PGMEA | 120 | 120 | 110 | 110 | 100 | 120 | 120 | 120 |

TABLE 1-3
Photosensitive resin composition (1)

| | | Example | | | | | |
|---|---|---|---|---|---|---|---|
| Component | Product name | 17 | 18 | 19 | 20 | 21 | 22 |
| Epoxy resin that is | 157S70 | 100 | 100 | | | | |
| trifunctional or more | EHPE-3150 | | | 100 | 100 | | |
| | HP7200H | | | | | 100 | 100 |
| Bifunctional epoxy | jER1001 (3,030) | — | — | — | — | — | — |
| resin (weight- | jER1007 (11,200) | 50 | 50 | 50 | 50 | 50 | 50 |
| average molecular | jER1009 (22,700) | — | — | — | — | — | — |
| weight Mw) | jER1256 (58,000) | — | — | — | — | — | — |
| Additive | PEG200 | | | | | | |
| | PEG600 | 2.5 | 5 | 2.5 | 5.0 | 2.5 | 5.0 |
| | PEG1000 | | | | | | |
| | Trimethylolpropane | | | | | | |
| | 1,6-Hexanediol | | | | | | |
| | Polyether polyol: diol | | | | | | |
| | Polyether polyol: triol | | | | | | |
| Photoacid generator | CPI-410S | 1.5 | 1.5 | 1.5 | 1.5 | 1.5 | 1.5 |
| | SP-172 | 3.3 | 3.3 | 3.3 | 3.3 | 3.3 | 3.3 |
| Acid generator | TPS-1000 | 0.5 | 0.5 | 0.5 | 0.5 | 0.5 | 0.5 |
| Silane coupling agent | A-187 | 5.0 | 5.0 | 5.0 | 5.0 | 5.0 | 5.0 |
| Solvent | PGMEA | 120 | 120 | 120 | 120 | 120 | 120 |

First, as illustrated in FIG. 4A, the PET film 12 having a thickness of 100 μm was prepared.

Next, as illustrated in FIG. 4B, the photosensitive resin composition (1) was applied onto the PET film 12 by a spin coating method, and was baked at 90° C. for 10 minutes so that its PGMEA solvent was volatilized. Thus, a dry film having a thickness of 15.0 μm was formed.

Next, as illustrated in FIG. 4C, the substrate 1 formed of silicon, which had, on its first surface side, the energy-generating elements 2 each formed of TaSiN, was prepared.

Next, as illustrated in FIG. 4D, SiCN was formed into a film having a thickness of 0.3 μm as the inorganic material layer 4 on the first surface of the substrate 1 by a plasma CVD method so as to cover the energy-generating elements 2. Subsequently, Ta was formed into a film having a thickness of 0.25 μm as the protective layer 5 by a sputtering method. Further, the inorganic material layer 4 and the protective layer 5 were subjected to patterning by a photolithography step and reactive ion etching.

Next, as illustrated in FIG. 4E, the supply port 3 penetrating from the first surface of the substrate 1 to a second surface opposite to the first surface was formed. The supply port 3 was formed by: forming an etching mask having an opening through the use of a positive photosensitive resin formed of OFPR (product name, manufactured by Tokyo Ohka Kogyo Co., Ltd.); and performing reactive ion etching from the second surface side of the substrate 1 through the opening of the etching mask. The reactive ion etching was performed with an ICP etching apparatus (manufactured by Alcatel Micro Machining Systems, model number: 8E) by a Bosch process. After the formation of the supply port 3, the etching mask was removed with a peeling liquid.

Next, as illustrated in FIG. 4F, the dry film 13 formed by using the photosensitive resin composition (1) was transferred onto the substrate 1. Specifically, the dry film 13 formed from the resin composition (1) was transferred from the base material 12 onto the surface of the substrate 1 having arranged therein the energy-generating elements 2 and the supply port 3 by using a lamination method while being heated at 70° C. and pressurized. After that, the base material 12 formed of a PET film was peeled from the dry film 13 with a peeling tape (not shown).

Next, as illustrated in FIG. 4G, the dry film 13 was subjected to pattern exposure with an i-line exposure stepper (manufactured by Canon Inc., product name: i5) at an exposure value of 10,000 J/m² through the photomask 14 having a flow path pattern. A heat treatment was further performed at 50° C. for 5 minutes to cure the exposed portion of the film. Thus, the flow path forming member 6 was formed.

Next, as illustrated in FIG. 4H, the dry film 15 was laminated on the substrate 1. Specifically, the photosensitive resin composition (2) shown in Table 2 was applied onto a PET film having a thickness of 100 μm, and was baked at 90° C. for 5 minutes so that its solvent was volatilized. Thus, a dry film having a thickness of 5.0 μm was formed. Next, the dry film 15 was transferred and laminated onto the dry film 13 after the exposure treatment by using a lamination method while being heated at 50° C.

TABLE 2

| | Product name | Part(s) by mass |
|---|---|---|
| Epoxy resin | 157S70 | 100 |
| Photoacid generator | CPI-410S | 0.5 |
| Silane coupling agent | A-187 | 5 |
| Solvent | PGMEA | 140 |

Next, as illustrated in FIG. 4I, the dry film 15 was subjected to pattern exposure with an i-line exposure stepper (manufactured by Canon Inc., product name: i5) at an exposure value of 1,100 J/m² through the photomask 16 having an ejection orifice pattern. A heat treatment was further performed at 90° C. for 5 minutes to cure the exposed portion of the film. Thus, the ejection orifice forming member 10 was formed.

Next, as illustrated in FIG. 4J, the uncured portions of the dry film 13 and the dry film 15 after the exposure treatments were developed with PGMEA for 1 hour to be collectively removed. Thus, the flow path 7 and the ejection orifices 8 were formed. The resultant was cured with heat at 200° C. to provide the liquid ejection head.

### Examples 23 to 36

A liquid ejection head was produced through steps illustrated in FIG. 5A to FIG. 5G by individually using each of the photosensitive resin compositions (1) shown in Table 3-1 and Table 3-2 for each of Examples. In each table, composition is represented by “part(s) by mass”.

TABLE 3-1
Photosensitive resin composition (1)

| | | Example | | | | | | | |
|---|---|---|---|---|---|---|---|---|---|
| Component | Product name | 23 | 24 | 25 | 26 | 27 | 28 | 29 | 30 |
| Epoxy resin | EPICLON N695 | 100 | 100 | 100 | 100 | 100 | 100 | 100 | 100 |
| Additive | PEG200 | 2.5 | 5 | | | | | | |
| | PEG600 | | | 1 | 2.5 | 5 | 10 | 30 | |
| | PEG1000 | | | | | | | | 5 |
| Photoacid | CPI-410S | 1.5 | 1.5 | 1.5 | 1.5 | 1.5 | 1.5 | 1.5 | 1.5 |
| generator | SP-172 | 3.3 | 3.3 | 3.3 | 3.3 | 3.3 | 3.3 | 3.3 | 3.3 |
| Acid generator | TPS-1000 | 0.5 | 0.5 | 0.5 | 0.5 | 0.5 | 0.5 | 0.5 | 0.5 |
| Silane coupling | A-187 | 5.0 | 5.0 | 5.0 | 5.0 | 5.0 | 5.0 | 5.0 | 5.0 |
| agent | | | | | | | | | |
| Solvent | PGMEA | 120 | 120 | 120 | 120 | 120 | 120 | 120 | 120 |

TABLE 3-2
Photosensitive resin composition (1)

| | Product | Example | | | | | |
|---|---|---|---|---|---|---|---|
| Component | name | 31 | 32 | 33 | 34 | 35 | 36 |
| Epoxy resin | 157S70 | 100 | 100 | | | | |
| that is | EHPE-3150 | | | 100 | 100 | | |
| trifunctional | HP7200H | | | | | 100 | 100 |
| or more | | | | | | | |
| Additive | PEG200 | | | | | | |
| | PEG600 | 2.5 | 5 | 2.5 | 5.0 | 2.5 | 5.0 |
| | PEG1000 | | | | | | |
| Photoacid | CPI-410S | 1.5 | 1.5 | 1.5 | 1.5 | 1.5 | 1.5 |
| generator | SP-172 | 3.3 | 3.3 | 3.3 | 3.3 | 3.3 | 3.3 |
| Acid generator | TPS-1000 | 0.5 | 0.5 | 0.5 | 0.5 | 0.5 | 0.5 |
| Silane coupling | A-187 | 5.0 | 5.0 | 5.0 | 5.0 | 5.0 | 5.0 |
| agent | | | | | | | |
| Solvent | PGMEA | 120 | 120 | 120 | 120 | 120 | 120 |

First, the substrate 1 having the inorganic material layer 4 and the protective layer 5 subjected to patterning in the same manner as in Example 1 on its surface having arranged therein the energy-generating elements 2 was prepared.

Next, as illustrated in FIG. 5A, a polymethyl isopropenyl ketone “ODUR-1010” (manufactured by Tokyo Ohka Kogyo Co., Ltd.) was applied as a positive photosensitive resin serving as a mold for the flow path 7 to the surface of the substrate 1 having arranged thereon the inorganic material layer 4 and the like by a spin coating method. The applied layer obtained by the application was subjected to a heat treatment at 120° C. for 6 minutes to form a positive photosensitive resin layer having a thickness of 14 μm.

Next, the positive photosensitive resin layer was exposed to a flow path pattern with an exposure apparatus UX-3000 (manufactured by Ushio Inc.), and the exposed portion of the positive photosensitive resin layer was developed with methyl isobutyl ketone (MIBK) to be removed. After that, the remainder was subjected to a rinsing treatment with isopropyl alcohol (IPA). Thus, the mold material 17 was formed.

Next, as illustrated in FIG. 5B, each of the photosensitive resin compositions (1) each having composition shown in Table 3-1 or Table 3-2 was individually used for forming the member 19 having the ejection orifices and the flow path, and was applied by a spin coating method. After that, the coated layer was subjected to a heat treatment (drying treatment) at 60° C. for 9 minutes to form, on the surface of the substrate 1 having arranged thereon the mold material 17, the negative photosensitive resin layer 18 covering the mold material 17 and having a thickness of 25 μm on the mold material 17.

Next, as illustrated in FIG. 5C, an exposing step was performed. Specifically, the negative photosensitive resin layer 18 was selectively exposed to light with an i-line exposure stepper (manufactured by Canon Inc., product name: i5) through the photomask 20 so that portions where the ejection orifices 8 were formed became non-exposed portions. Thus, as illustrated in FIG. 5D, the member 19 was formed. An exposure intensity was set to 5,000 J/m² in each of Examples 23 to 30, 33, and 34, to 1,100 J/m² in each of Examples 31 and 32, or to 15,000 J/m² in each of Examples 35 and 36.

Next, the negative photosensitive resin layer 18 subjected to the exposure treatment was subjected to a heat treatment at 95° C. for 4 minutes. After that, as illustrated in FIG. 5E, the non-exposed portions were developed with a mixed liquid containing xylene and methyl isobutyl ketone (MIBK) (mass ratio: 6/4) and subjected to a rinsing treatment with xylene to form the ejection orifices 8.

Next, as illustrated in FIG. 5F, the substrate 1 was subjected to anisotropic etching with tetramethylammonium hydroxide (TMAH) that was an alkaline solution through the use of a resin layer having resistance to TMAH as an etching mask. Thus, the supply port 21 was formed.

After that, as illustrated in FIG. 5G, the substrate 1 was immersed in methyl lactate so that the mold material 17 was dissolved and removed. Thus, the flow path 7 was formed. After that, the resultant was cured with heat at 200° C. to provide the liquid ejection head.

[Evaluation]

### <Adhesiveness Between Inorganic Material Layer 4 and Member for Forming Flow Path>

After the developing step of each liquid ejection head, a bonding state between the inorganic material layer 4 and the flow path forming member 6, or between the inorganic material layer 4 and a member for forming a flow path was observed with a metalloscope, and was evaluated by the following criteria. The term “member for forming a flow path” refers to the flow path forming member 6 in each of Examples 1 to 22 and Comparative Examples 1 to 6, or to the member 19 having the flow path and the ejection orifices in each of Examples 23 to 36 and Comparative Examples 7 to 9.

A: No peeling occurs between the inorganic material layer 4 and the member for forming a flow path.
B: Peeling occurs between the inorganic material layer 4 and the member for forming a flow path.

In each of the liquid ejection heads produced in Examples described above, no peeling occurred between the inorganic material layer 4 and the member for forming a flow path.

<Falling Amount>

In the production process for each of the liquid ejection heads of Examples 1 to 22 and Comparative Examples 1 to 5, after the lamination of the dry film 15, the depth of the falling of the entirety of a portion where the dry film was laminated in the upper portion of the supply port 3 was measured, and the resultant value was adopted as a falling amount. Specifically, the extent to which the exposed surface of the dry film 15, which was a uniform flat surface in a region that did not correspond to the position of the supply port 3, was depressed toward the supply port 3 at the position of the opening of the supply port 3 was adopted as the falling amount. The measurement of the falling amount was performed by measuring how deep the deepest portion was from the uniform surface of the dry film 15 with a laser microscope (manufactured by Keyence Corporation, product name: VD-9710). An evaluation was performed based on the resultant falling amount by the following criteria.

A: The falling amount is less than 0.5 μm.
B: The falling amount is 0.5 μm or more and less than 1.5 μm.
C: The falling amount is 1.5 μm or more.

All the liquid ejection heads produced in Examples described above each had a falling amount of less than 0.5 μm.

<Pattern Shape>

A pattern shape was evaluated by the following criteria through the observation of the pattern side walls of a member for forming a flow path with a scanning electron microscope (manufactured by Hitachi, Ltd., product name: S-4700) at a magnification of 5,000.

A: Unevenness is absent.
B: Unevenness is present.

In each of the liquid ejection heads produced in Examples described above, no unevenness was observed on the pattern side walls, and hence the pattern shape was satisfactory.

### Comparative Examples 1 to 9

A liquid ejection head was produced by individually using each of the photosensitive resin compositions (1) each having composition shown in Table 4 in the same manner as in Example 1 in each of Comparative Examples 1 to 6, or in the same manner as in Example 23 in each of Comparative Examples 7 to 9.

In the liquid ejection head produced in Comparative Example 2, 3, or 4, peeling partially occurred between the inorganic material layer 4 and the flow path forming member 6 at the time of the development.

Falling amounts and pattern shapes were evaluated in Comparative Examples 1 to 6 as in Examples. The falling amounts were less than 0.5 μm in the liquid ejection heads of Comparative Examples 1 to 5, but the falling amount was 1.5 μm or more in the liquid ejection head of Comparative Example 6. In addition, the pattern shapes of Comparative Examples 1 to 9 were evaluated. As a result, in each of Comparative Examples 1 and 9, unevenness was observed on the pattern side walls of the flow path forming member 6.

TABLE 4
Photosensitive resin composition (1)

| | | Comparative Example | | | | | | | | |
|---|---|---|---|---|---|---|---|---|---|---|
| Component | Product name | 1 | 2 | 3 | 4 | 5 | 6 | 7 | 8 | 9 |
| Epoxy resin that | EPICLON N695 | 100 | 100 | 100 | 100 | 100 | 100 | | | |
| is trifunctional | 157S70 | | | | | | | 100 | | |
| or more | EHPE-3150 | | | 10 | | | | | 100 | |
| | HP7200H | | | | | | | | | 100 |
| Bifunctional epoxy | jER1001 (3,030) | — | — | — | — | — | 50 | — | — | — |
| resin (weight- | jER1007 (11,200) | 50 | 50 | 50 | 50 | 50 | — | — | — | — |
| average molecular | jER1009 (22,700) | — | — | — | — | — | — | — | — | — |
| weight Mw) | jER1256 (58,000) | — | — | — | — | — | — | — | — | — |
| Additive | PEG3000 | 5 | | | | | | | | |
| | Butanol | | 5 | | | | | | | |
| | 1,4-HFAB | | | | 5 | | | | | |
| | Polyether polyol: tetraol | | | | | 5 | | | | |
| Photoacid generator | CPI-410S | 1.5 | 1.5 | 1.5 | 1.5 | 1.5 | 1.5 | 1.5 | 1.5 | 1.5 |
| | SP-172 | 3.3 | 2.5 | 3.3 | 3.3 | 3.3 | 2.5 | 3.3 | 2.5 | 3.3 |
| Acid generator | TPS-1000 | 0.5 | 0.3 | 0.5 | 0.5 | 0.5 | 0.3 | 0.5 | 0.3 | 0.5 |
| Silane coupling agent | A-187 | 5.0 | 5.0 | 5.0 | 5.0 | 5.0 | 5.0 | 5.0 | 5.0 | 5.0 |
| Solvent | PGMEA | 120 | 120 | 120 | 120 | 120 | 120 | 120 | 120 | 120 |

The respective evaluation results obtained in Examples and Comparative Examples described above are collectively shown in Table 5.

TABLE 5

| | Example | | | | | | | | | | | | | | | | | |
|---|---|---|---|---|---|---|---|---|---|---|---|---|---|---|---|---|---|---|
| | 1 | 2 | 3 | 4 | 5 | 6 | 7 | 8 | 9 | 10 | 11 | 12 | 13 | 14 | 15 | 16 | 17 | 18 |
| Adhesiveness | A | A | A | A | A | A | A | A | A | A | A | A | A | A | A | A | A | A |
| Falling | A | A | A | A | A | A | A | A | A | A | B | A | A | A | A | A | A | A |
| amount | | | | | | | | | | | | | | | | | | |
| Pattern shape | A | A | A | A | A | A | A | A | A | A | A | A | A | A | A | A | A | A |
| | Example | | | | | | | | | | | | | | | | | |
| | 19 | 20 | 21 | 22 | 23 | 24 | 25 | 26 | 27 | 28 | 29 | 30 | 31 | 32 | 33 | 34 | 35 | 36 |
| Adhesiveness | A | A | A | A | A | A | A | A | A | A | A | A | A | A | A | A | A | A |
| Falling | A | A | A | A | — | — | — | — | — | — | — | — | — | — | — | — | — | — |
| amount | | | | | | | | | | | | | | | | | | |
| Pattern shape | A | A | A | A | A | A | A | A | A | A | A | A | A | A | A | A | A | A |

| | Comparative Example | | | | | | | | |
|---|---|---|---|---|---|---|---|---|---|
| | 1 | 2 | 3 | 4 | 5 | 6 | 7 | 8 | 9 |
| Adhesiveness | A | B | B | B | A | A | A | A | A |
| Falling | A | A | A | A | A | C | — | — | — |
| amount | | | | | | | | | |
| Pattern shape | B | A | A | A | A | A | A | A | B |

<Ink Resistance>

The flow path of each of the liquid ejection heads produced in Examples 1 to 36 and Comparative Examples 1 to 9 was filled with an ink shown in Table 6 below, and the head was left to stand in an oven at 70° C. for 90 days.

TABLE 6

| Blended component | Part(s) by mass |
|---|---|
| Diethylene glycol | 10.0 |
| 2-Pyrrolidone | 30.0 |
| 1,2-Hexanediol | 7.0 |
| ACETYLENOL | 1.0 |
| Black pigment | 3.0 |
| Pure water | 49.0 |

A bonding state between the inorganic material layer 4 and a member for forming a flow path after the standing was observed with a metalloscope, and was evaluated by the following criteria.

A: Even after the storage at 70° C. for 90 days, no peeling occurs between the inorganic material layer 4 and the flow path forming member 6 or the member 19.
B: After the storage at 70° C. for 90 days, peeling that has not been observed at the time of the completion of the liquid ejection head occurs between the inorganic material layer 4 and the flow path forming member 6 or the member 19.

<Printing Evaluation>

Each of the liquid ejection heads produced in Examples and Comparative Examples was filled with an ink formed of ethylene glycol, urea, isopropyl alcohol, N-methylpyrrolidone, a black dye, and water at a ratio of 5/3/2/5/3/82 (each value was on a mass basis). After the filling, the head was stored at 70° C. for 90 days, and then a printing evaluation was performed.

The evaluation results of the ink resistance and the printing evaluation are shown in Table 7.

TABLE 7

| | Example | | | | | | | | |
|---|---|---|---|---|---|---|---|---|---|
| | 1 | 2 | 3 | 4 | 5 | 6 | 7 | 8 | 9 |
| Ink | A | A | A | A | A | A | A | A | A |
| resistance | | | | | | | | | |
| Print | Satisfactory | Satisfactory | Satisfactory | Satisfactory | Satisfactory | Satisfactory | Satisfactory | Satisfactory | Satisfactory |
| quality | | | | | | | | | |

| | Example | | | | | | | | |
|---|---|---|---|---|---|---|---|---|---|
| | 10 | 11 | 12 | 13 | 14 | 15 | 16 | 17 | 18 |
| Ink | A | A | A | A | A | A | A | A | A |
| resistance | | | | | | | | | |
| Print | Satisfactory | Satisfactory | Satisfactory | Satisfactory | Satisfactory | Satisfactory | Satisfactory | Satisfactory | Satisfactory |
| quality | | | | | | | | | |

| | Example | | | | | | | | |
|---|---|---|---|---|---|---|---|---|---|
| | 19 | 20 | 21 | 22 | 23 | 24 | 25 | 26 | 27 |
| Ink | A | A | A | A | A | A | A | A | A |
| resistance | | | | | | | | | |
| Print | Satisfactory | Satisfactory | Satisfactory | Satisfactory | Satisfactory | Satisfactory | Satisfactory | Satisfactory | Satisfactory |
| quality | | | | | | | | | |

| | Example | | | | | | | | |
|---|---|---|---|---|---|---|---|---|---|
| | 28 | 29 | 30 | 31 | 32 | 33 | 34 | 35 | 36 |
| Ink | A | A | A | A | A | A | A | A | A |
| resistance | | | | | | | | | |
| Print | Satisfactory | Satisfactory | Satisfactory | Satisfactory | Satisfactory | Satisfactory | Satisfactory | Satisfactory | Satisfactory |
| quality | | | | | | | | | |

| | Comparative Example | | | | | | | | |
|---|---|---|---|---|---|---|---|---|---|
| | 1 | 2 | 3 | 4 | 5 | 6 | 7 | 8 | 9 |
| Ink | B | B | B | B | B | B | B | B | B |
| resistance | | | | | | | | | |
| Print | Reduction | Reduction | Reduction | Reduction | Reduction | Reduction | Reduction | Reduction | Reduction |
| quality | | | | | | | | | |

In each of the liquid ejection heads produced in Examples 1 to 36, the ink resistance of the inorganic material layer and the member for forming a flow path was satisfactory, and the print quality was also satisfactory. Meanwhile, in each of the liquid ejection heads produced in Comparative Examples 1 to 9, the ink resistance was low, and a reduction in print quality was observed under the influence of the occurrence of the peeling between the inorganic material layer and the member for forming a flow path. In each of Comparative Examples 1 and 9, the reduction in print quality was more remarkable than that in any other comparative example under the influence of the deterioration of the pattern shape. In addition, in Comparative Example 6, the reduction in print quality was even more remarkable because the falling of the entirety of the resin composition layer into the supply port was larger than that in any other comparative example.

As described above, it is found that, according to at least one embodiment of the present disclosure, the microstructure and the liquid ejection head each having bonding reliability between the inorganic material layer and the organic material layer can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2018-246290, filed Dec. 27, 2018, which is hereby incorporated by reference herein in its entirety.

What is claimed is:

1. A method of producing a microstructure comprising:
forming a resin layer from a photosensitive resin composition on a substrate;
exposing the resin layer to a microstructure pattern to form a cured portion as a result of the exposure and an uncured portion as a result of non-exposure; and
removing the uncured portion from the substrate through development to provide a microstructure pattern having the cured portion,
wherein the photosensitive resin composition contains an epoxy resin, a crosslinking agent containing a polyhydric alcohol that is bifunctional or trifunctional with respect to a terminal hydroxy group, and that is free of a perfluoroalkyl group and a perfluoroalkylene group, a photoacid generator, and a solvent,
wherein the polyhydric alcohol has a number-average molecular weight of less than 3,000, and
wherein a surface of the substrate on which the resin layer is formed has one of unevenness and an opening.

2. The method of producing a microstructure according to claim 1, wherein the surface of the substrate on which the resin layer is formed includes an inorganic material layer.

3. The method of producing a microstructure according to claim 2, wherein the inorganic material layer contains at least one of silicon oxide, silicon carbide, silicon carbonitride, silicon oxycarbide, or a metal.

4. The method of producing a microstructure according to claim 1, wherein the epoxy resin contains an epoxy resin having a weight-average molecular weight of 5,000 or more.

5. The method of producing a microstructure according to claim 4, wherein the epoxy resin having a weight-average molecular weight of 5,000 or more is a bifunctional epoxy resin.

6. The method of producing a microstructure according to claim 5, wherein the bifunctional epoxy resin having a weight-average molecular weight of 5,000 or more is an epoxy resin having a bisphenol skeleton.

7. The method of producing a microstructure according to claim 1, wherein the crosslinking agent contains at least one selected from the group consisting of a high-molecular weight polyhydric alcohol having a number-average molecular weight of 200 or more and less than 3,000, and having a repeating structure in a molecule thereof, and a low-molecular weight polyhydric alcohol having a number-average molecular weight of less than 200 and a boiling point of 200° C. or more.

8. The method of producing a microstructure according to claim 1, wherein the epoxy resin contains an epoxy resin that is trifunctional or more.

9. The method of producing a microstructure according to claim 1, wherein the epoxy resin contains at least one selected from the group consisting of an epoxy resin having a bisphenol skeleton, an epoxy resin having a phenol novolac skeleton, an epoxy resin having a cresol novolac skeleton, an epoxy resin having a norbornene skeleton, an epoxy resin having a terpene skeleton, an epoxy resin having a dicyclopentadiene skeleton, and an epoxy resin having an oxycyclohexane skeleton.

10. The method of producing a microstructure according to claim 1, wherein the forming a resin layer includes applying the photosensitive resin composition to the substrate to form a coated layer and drying the coated layer.

11. The method of producing a microstructure according to claim 1, wherein the forming a resin layer includes applying the resin composition onto a base material to provide a coated layer, forming a dry film from the coated layer, and transferring the dry film from the base material onto the substrate.

12. The method of producing a microstructure according to claim 7, wherein the high-molecular weight polyhydric alcohol comprises at least one of compounds represented by the following formulae (a) to (c): 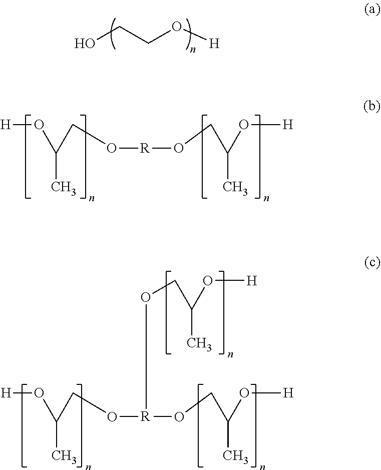
in the formulae, respective “n”s each independently represent a natural number, and respective Rs each independently represent an aliphatic group that may have an oxygen atom and/or a nitrogen atom, and that may be cyclic, or an aromatic group that may have an oxygen atom, and each have 1 to 15 carbon atoms.

13. The method of producing a microstructure according to claim 7, wherein the low-molecular weight polyhydric alcohol comprises at least one selected from the group consisting of 1,2-hexanediol, 1,6-hexanediol, glycerin, trimethylolpropane, 3-methyl-1,5-pentanediol, 1,2,6-hexanetriol, 1,5-dihydroxypentan-3-one, 6-hydroxycaproic acid, and 2-hydroxymethyl-1,3-propanediol.

14. The method of producing a microstructure according to claim 1, wherein an addition amount of the polyhydric alcohol is 0.5% or more and 30.0% or less with respect to an entire mass of the epoxy resin in the photosensitive resin composition.

15. The method of producing a microstructure according to claim 14, wherein the addition amount of the polyhydric alcohol is 1.0% or more and 10.0% or less with respect to the entire mass of the epoxy resin in the photosensitive resin composition.

16. A method of producing a liquid ejection head including a substrate, and a member having an ejection orifice and a flow path, the method comprising:
forming a resin layer from a photosensitive resin composition (1) on the substrate; and
exposing and developing the resin layer on the substrate to form at least a portion having the flow path of the member from a cured portion as a result of the exposure,
wherein the photosensitive resin composition (1) contains an epoxy resin, a crosslinking agent containing a polyhydric alcohol that is bifunctional or trifunctional with respect to a terminal hydroxy group, and that is free of a perfluoroalkyl group and a perfluoroalkylene group, a photoacid generator, and a solvent,
wherein the polyhydric alcohol has a number-average molecular weight of less than 3,000, and
wherein a surface of the substrate on which the resin layer is formed has one of unevenness and an opening.

17. The method of producing a liquid ejection head according to claim 16, wherein the surface of the substrate on which the resin layer is formed includes an inorganic material layer.
